(19) United States
(12) Patent Application Publication
(10) Pub. No.: US 2010/0123523 A1
(43) Pub. Date: May 20, 2010

(54) STANDING WAVE OSCILLATORS

(75) Inventors: Richard Walsworth, Menlo Park, CA (US); Koji Takinami, Saratoga, CA (US)

Correspondence Address: SNELL & WILMER L.L.P. (Panasonic), 600 ANTON BOULEVARD, SUITE 1400, COSTA MESA, CA, 92626, US

(73) Assignee: Matsushita Electric Industrial Co., Ltd.

(21) Appl. No.: 12/272,307

(22) Filed: Nov. 17, 2008

(51) Int. Cl. H03B 1/00; H03B 28/00

(52) U.S. Cl. 331/108 R; 331/172

(57) ABSTRACT

A standing wave oscillator (SWO) is formed from a microstrip transmission line or a stripline transmission line having a closed-loop single signal trace. Using the microstrip transmission line or stripline transmission line, the SWO can be formed with bends and in complex shapes, which are not so easily realized or possible using coplanar stripline (CPS) transmission lines. Simulation results demonstrate that the microstrip and stripline transmission line based SWOs provide superior operational characteristics (e.g., higher quality factors (Qs)) compared to a CPS transmission line based SWO of similar size and geometry.

### FIELD OF THE INVENTION

The present invention relates to electronic oscillators. More specifically, the present invention relates to standing wave oscillators (SWOs).

### BACKGROUND OF THE INVENTION

Electronic oscillators are electronic circuits that produce oscillating electrical signals such as sine waves or a square waves. They are used in both analog and digital systems, and are essential components of wireless communications transmitters and receivers.

Many modern electronic systems require electronic oscillators capable of generating signals at microwave and millimeter-wave frequencies. Conventional electronic oscillators (e.g., those using lumped element tank circuits) are limited in their ability to generate signals at these frequencies while also maintaining low phase noise. For this reason, alternative oscillator mechanisms have been sought. One category of electronic oscillators that has gained recent interest as a possible alternative is the category of oscillators known as “wave-based” oscillators. Wave-based oscillators dispense with the need for lumped element tank circuits and, instead, rely on the distributed inductance and capacitance of a transmission line to achieve oscillation. Recent developments in wave-based oscillator design have demonstrated the ability of wave-based oscillators to operate at high frequencies, low power, and low phase noise. These developments have made wave-based oscillators attractive candidates for microwave and millimeter-wave applications.

One type of wave-based oscillator that has gained recent attention is the standing wave oscillator (SWO). FIG. 1A is a drawing of a simple quarter-wavelength (λ/4) SWO 100. A cross-sectional view of the λ/4 SWO 100 along line 1B-1B is shown in FIG. 1B. The λ/4 SWO 100 comprises a coplanar stripline (CPS) transmission line including first and second signal lines (i.e., “traces”) 102 and 104, first and second ground planes 106 and 108 (shown in FIG. 1B only), a pair of cross-coupled inverters 110 at one end of the CPS transmission line and a short 112 at the opposing end. The first and second signal traces 102 and 104 each have a length l and are separated from one another by a distance s. The first and second signal traces 102 and 104 and associated first and second ground planes 106 and 108 are formed on a silicon or dielectric substrate 114, all within the same horizontal plane, as can be best seen in the cross-sectional drawing in FIG. 1B.

As the λ/4 SWO 100 operates, forward traveling waves propagate along the CPS transmission line from the pair of cross-coupled inverters 110 to the short 112, where they are reflected into reverse traveling waves. The forward and reverse traveling waves superpose to form standing waves. Boundary conditions allow standing wave mode at l=n×λ/4, where n=1, 3, 5, . . . and λ is the wavelength of the fundamental mode standing wave. The higher order modes (n>1), are insignificant relative to the fundamental mode (n=1) due to substantial high frequency losses. The pair of cross-coupled inverters 110 operates to compensate for losses experienced by the forward and reverse traveling waves as they propagate along the CPS transmission line.

Instead of using a short 112, the CPS transmission line of the λ/4 SWO 100 may be connected in a closed-loop, as shown in FIG. 2, to form a circular SWO 200. The circular SWO 200 includes first and second signal traces 202 and 204 formed in a closed loop of length (i.e., perimeter) l, width w, and separation s, a first pair of cross-coupled inverters 206 at a first port P1-P2 and a second pair of cross-coupled inverters 208 at as second port P3-P4. The first and second ground planes (not shown in the drawing) are formed in the same horizontal plane as the first and second signal traces 202 and 204. Collectively, the first and second signal traces 202 and 204 and first and second ground planes comprise a closed-loop circular CPS transmission line in the shape of a ring. The purpose of the connections 210 and 212 connecting P1 to P3 and P2 to P4 is to ensure that the first and second ports P1-P2 and P3-P4 always remain in opposite phase, which is possible only for odd modes. Hence, even modes may be suppressed by use of the connections 210 and 212, essentially leaving only the fundamental mode, since higher-order odd modes are naturally suppressed due to high frequency loss.

Energy injected into the circular SWO 200 is split symmetrically into two opposing traveling waves—a clockwise (CW) traveling wave v(z,t)=A₁ cos(ωtβz) and a counter-clockwise (CCW) traveling wave v(z,t)=A₂ cos(ωt+βz), as shown in FIG. 2. If A₁=A₂, and the CPS transmission line is symmetric about φ=0, the CW and CCW traveling waves superpose to form standing wave v(z,t)=2A₂ cos(ωt) cos(βz). The first and second pairs of cross-coupled inverters 206 and 208 compensate for losses experienced by the CCW and CW traveling waves as they propagate along the CPS transmission line, similar to how the pair of cross-coupled inverters 110 of the λ/4 SWO 100 in FIGS. 1A and 1B.

The wave characteristics of the standing wave are determined by the periodic boundary conditions of the closed-loop CPS transmission line. The periodic boundary conditions require that the voltage V(φ) at any angle φ along the ring be equal to V(φ+2π). Consequently, standing wave modes must correspond to l=nλ, where n=1, 2, 3, . . . and λ is the wavelength of the fundamental mode standing wave. The CCW and CW traveling waves and the composite standing wave for n=1 are shown in FIGS. 4A-C. FIG. 4C shows that the composite standing wave has a positive peak at the top of the ring (i.e., at λ=0°), a negative peak at the bottom of the ring (i.e., at λ/2=180°), and nulls at λ/4=−90° and 3λ/4=+90°.

Although CPS transmission line based SWOs offer various advantages and benefits over more conventional lumped oscillators, they have a number of drawbacks. One especially significant drawback is that it is difficult to form closed-loop SWOs of complex shapes (i.e., other than circular) using CPS transmission lines. As explained above, CPS transmission line based SWOs require a pair of signal lines and attending ground planes, all within the same horizontal plane. This makes it difficult, or in some cases even impossible, to form complex bends in the CPS transmission line without disrupting the symmetry of the SWO about the φ=0 line. Symmetry about the φ=0 line is essential. Absent symmetry, the forward and reverse traveling waves do not combine as desired to form a standing wave. Instead, any asymmetry results in only traveling waves or a combination of rotating and standing waves, either of which detracts from use of the CPS transmission line based SWO as a practical oscillator.

An SWO formed from a CPS transmission line also exhibits a high trace-to-trace capacitance and a lower than desired quality factor (Q). In general, the Q of a frequency dependent system is defined as the ratio of a peak or resonant frequency of the system to the frequency bandwidth of the system. In the context of an oscillator, the Q provides an indication of the frequency selectiveness of the oscillator. In many systems, such as in wireless communications systems, an oscillator with a high Q is often required for low phase noise. Unfortunately, many state-of-the art and next generation applications require oscillators having higher Qs than can be realized using CPS transmission line based SWOs.

It would be desirable, therefore, to have SWOs that avoid the drawbacks and limitation of CPS transmission line based SWOs.

### SUMMARY OF THE INVENTION

An exemplary SWO includes a transmission line having a closed-loop single signal trace, one or more ground planes, and a pair of cross-coupled inverters. The one or more ground planes are formed in one or more planes that are parallel to but different than a plane within which the closed-loop single signal trace is formed. The pair of cross-coupled inverters has a first port coupled to a first location on the closed-loop single signal trace and a second port coupled to a second location on the closed-loop single signal trace. The closed-loop single signal trace is symmetrical about a line passing through the first and second ports of the pair of cross-coupled inverters.

According to one aspect of the invention, the closed-loop single signal trace SWO is formed from a microstrip transmission line or a stripline transmission line. Unlike CPS transmission line based SWOs, which require two signal traces and two attending ground planes all in the same horizontal plane, microstrip and stripline transmission lines use only a single signal trace with grounds in planes different from the plane in which the signal trace is formed. This allows bends and complex-shaped SWOs to be formed without disrupting the symmetry of the SWOs.

Simulation results are provided which demonstrate that the closed-loop single signal trace SWOs of the present invention offer superior operational characteristics (e.g., higher quality factors (Qs)) compared to SWOs formed from CPS transmission lines of similar size and geometry. The superior operational characteristics make the SWOs of the present invention attractive for use in existing and next generation high-frequency wide bandwidth communications systems, particularly those designed to operate at microwave and millimeter-wave frequencies.

Further features and advantages of the present invention, including a description of the structure and operation of the above-summarized and other exemplary embodiments of the invention, are described in detail below with respect to accompanying drawings, in which like reference numbers are used to indicate identical or functionally similar elements.

### BRIEF DESCRIPTION OF THE DRAWINGS

FIG. 1A is a layout view drawing of a simple quarter-wavelength (λ/4) standing wave oscillator (SWO);

FIG. 1B is a cross-sectional drawing of the λ/4 SWO in FIG. 1A;

FIG. 2 is a layout view drawing of a circular SWO formed from a closed-loop coplanar stripline (CPS) transmission line;

FIGS. 3A-C are graphs of the counter-clockwise (CCW) and clockwise (CW) traveling waves (FIGS. 3A and 3B) and the composite standing wave (FIG. 3C) formed from the superposition of the CCW and CW traveling waves as a function of position along the closed-loop CPS transmission line for the circular SWO in FIG. 2;

FIG. 4 is a layout view drawing of a “figure 8” SWO, according to an embodiment of the present invention;

FIG. 5 is a circuit diagram of a complementary metal oxide semiconductor (CMOS) latch that can be used to implement the pair of cross-coupled inverters in the SWO in FIG. 4;

FIGS. 6A and 6B are perspective and cross-sectional view drawings respectively, of a microstrip transmission line, which is used to form the closed-loop transmission line of the SWO in FIG. 4 in one embodiment of the present invention;

FIGS. 7A and 7B are perspective and cross-sectional view drawings respectively, of a stripline transmission line, which is used to form the closed-loop transmission line of the SWO in FIG. 4 in another embodiment of the present invention;

FIG. 8 is a layout view drawing of a simulated CPS transmission line based “figure 8” SWO, which was modeled and compared to the microstrip transmission line based “figure 8” SWO in FIG. 9;

FIG. 9 is a layout view drawing of a simulated microstrip transmission line based “figure 8” SWO, which was modeled and compared to the CPS transmission line based “figure 8” SWO in FIG. 8;

FIG. 10 is a graph comparing the inductance and Q of the simulated CPS transmission line based “figure 8” SWO in FIG. 8 to the inductance and Q of the simulated microstrip transmission line based “figure 8” SWO in FIG. 9 as a function of frequency;

FIG. 11 is a layout view drawing of a quadrature SWO, according to an embodiment of the present invention;

FIG. 12 is a circuit diagram of the first and second pairs of cross-coupled inverters of the I and Q oscillators of the quadrature SWO in FIG. 11, illustrating how the first and second pairs of cross-coupled inverters are configured; and

FIG. 13 is a circuit diagram of the first and second pairs of cross-coupled inverters of the I and Q oscillators of the quadrature SWO in FIG. 11, illustrating how varactors may be included to provide the ability to frequency tune the quadrature SWO.

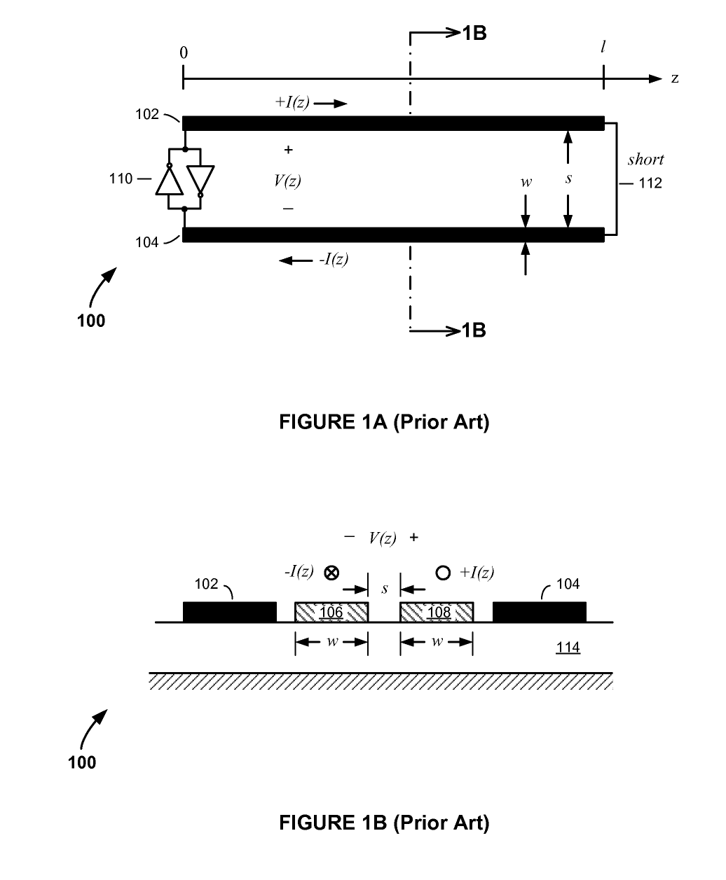

### DETAILED DESCRIPTION

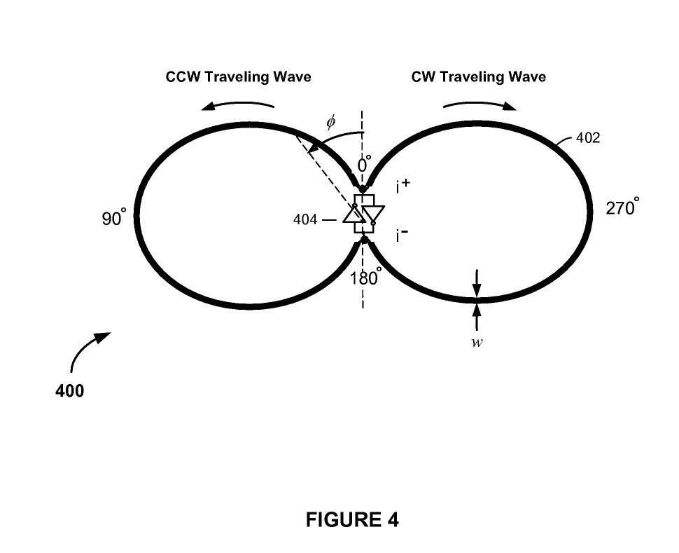

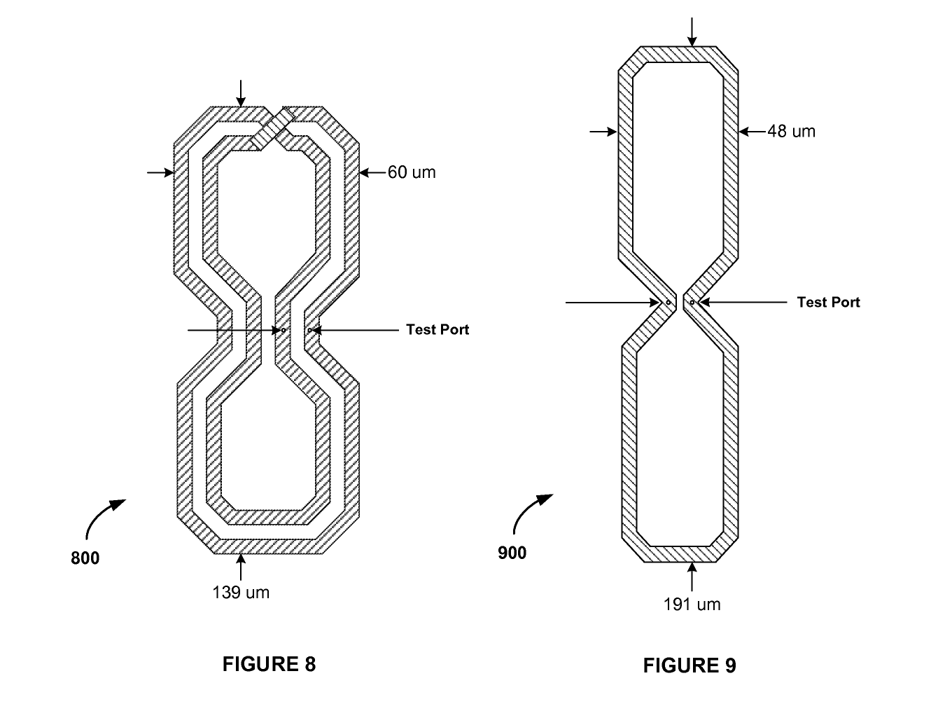

Referring to FIG. 4, there is shown a standing wave oscillator (SWO) 400, according to an embodiment of the present invention. The SWO 400 comprises a closed-loop transmission line 402 of width w and a pair of cross-coupled inverters 404. The closed-loop transmission line 402 is formed in the shape of a “figure 8”, such that there is a small physical space between which the pair of cross-coupled inverters 404 is connected. Forming the closed-loop in the shape of a “figure 8” rather than in the shape of a circle reduces the physical distance between the top and bottom of the transmission line 402. The reduced separation reduces the time delay and interconnection loss between the between the top and bottom of the transmission line 402, which can be important when the SWO 400 is used at microwave or millimeter-wave frequencies.

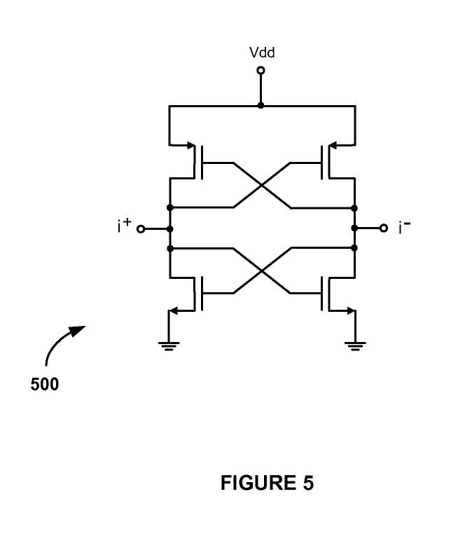

In one embodiment of the invention, the SWO 400 is formed in an integrated circuit fabricated according to a complementary metal oxide semiconductor (CMOS) manufacturing process, and the pair of cross-coupled inverters 404 comprises a CMOS latch 500 formed from first and second cross-coupled CMOS inverters, as shown in the circuit diagram in FIG. 5.

As indicated by the arrows along the outer periphery of the closed-loop transmission line 402 of the SWO 400 in FIG. 4, energy injected into the closed-loop transmission line 402 results in opposing traveling waves, one traveling in a clockwise (CW) direction and the other traveling in a (CCW) counter-clockwise direction. The CW and CCW traveling waves combine to form a standing wave along the closed-loop transmission line 402. The pair of cross-coupled inverters 404 compensates for losses the CW and CCW traveling waves experience as they propagate along the closed-loop transmission line 402.

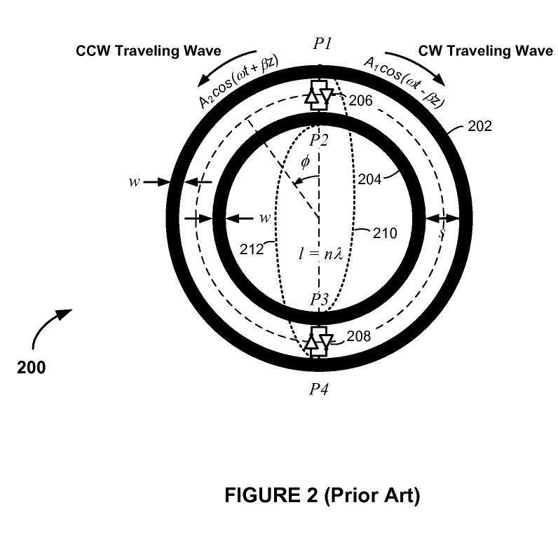

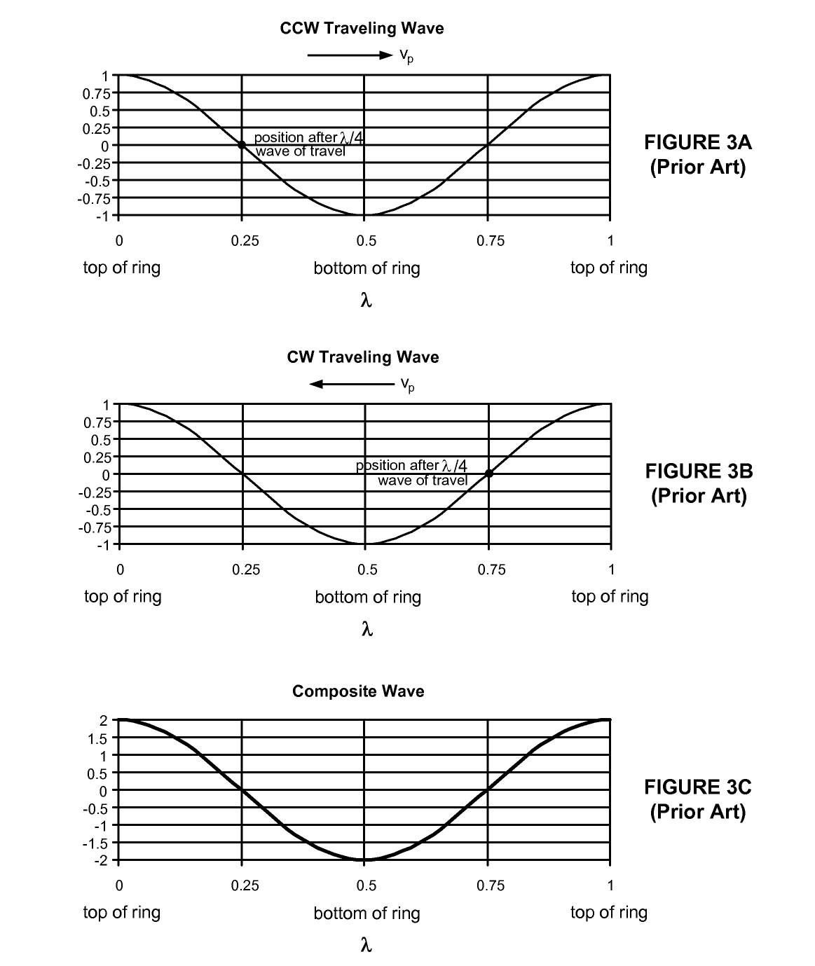

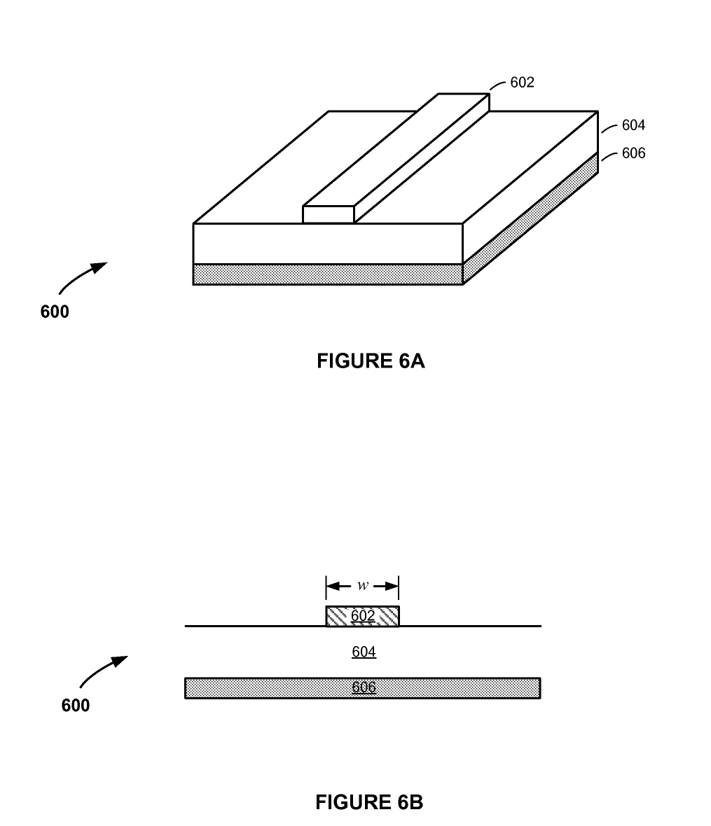

According to one embodiment of the invention, the closed-loop transmission line 402 is formed from a microstrip transmission line. As shown in FIGS. 6A and 6B, which are perspective and cross-sectional view drawings, respectively, the microstrip transmission line 600 comprises a single signal line (or “trace”) 602, formed over a dielectric or semiconductor substrate 604 and a ground plane 606. Because only a single signal trace is used, the “figure 8” shape of the SWO 400 is significantly easier to form than if attempted using a coplanar stripline (CPS) transmission line. As was explained above in connection with FIGS. 2A-B and FIG. 3, using a CPS transmission line makes it difficult to form bends and complex-shaped SWOs without disrupting the symmetry of SWO, since the CPS transmission line requires two signal traces and two attending ground planes all in the same horizontal plane.

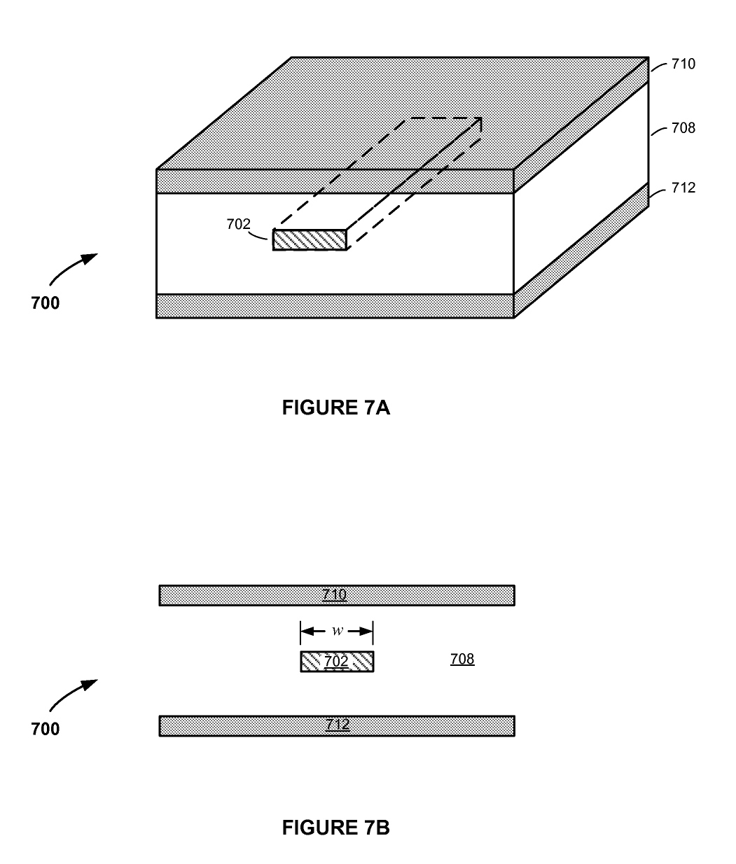

According to an alternative embodiment of the invention, the closed-loop transmission line 402 is formed from a stripline transmission line. As shown in FIGS. 7A and 7B, which are perspective and cross-sectional view drawings, respectively, the stripline transmission line 700 comprises a single signal trace 702 formed in a dielectric or semiconductor layer 708 bounded by upper and lower ground planes 710 and 712. Similar to the microstrip transmission line 600 in FIGS. 6A-B, since only a single signal trace 702 is used, forming symmetrical and complex-shaped SWOs is much easier than it would be using a CPS transmission line.

Besides being able to more easily form bends and complex-shaped SWOs, simulations have shown that the SWO 400 in FIG. 4, when formed from the microstrip line transmission line 600 (like that in FIGS. 6A-B) or the stripline transmission line 700 (like that in FIGS. 7A-B), has superior operational characteristics compared to SWOs formed from CPS transmission lines of similar size and geometry. FIGS. 8 and 9 show layout characteristics of a simulated CPS transmission line based SWO 800 and a simulated microstrip transmission line based SWO 900, respectively, including the dimensions of the simulated SWOs 800 and 900. The arrows next to the “test ports” indicate the location at which energy is injected.

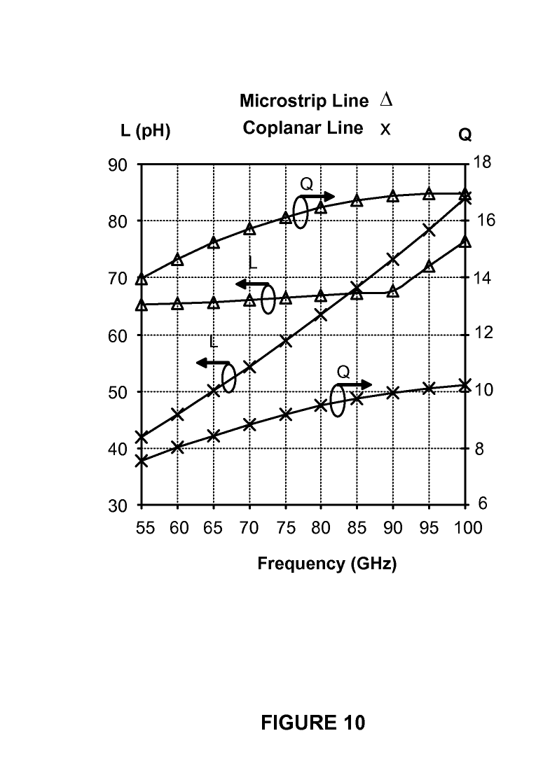

The inductance and quality factor (Q) of the simulated SWOs 800 and 900 over a frequency range of interest (55-100 GHz) are shown in the graph in FIG. 10. It is seen that the Q of the simulated microstrip transmission line based SWO 900 is nearly two times greater than the Q of the simulated CPS transmission line based SWO 800 over the frequency range of interest. Further, it is seen that the inductance of the simulated CPS transmission line based SWO 800 increases with increasing frequency. This increase is due to the line approaching resonance because of the higher trace-to-trace capacitance of the simulated CPS transmission line based SWO 800. By contrast, the inductance of the simulated microstrip transmission line based SWO 900 is seen to remain essentially constant up to about 90 GHz. Hence, the simulation results reveal that the microstrip transmission line based SWO has superior operational characteristics over that of an SWO formed from a CPS transmission line.

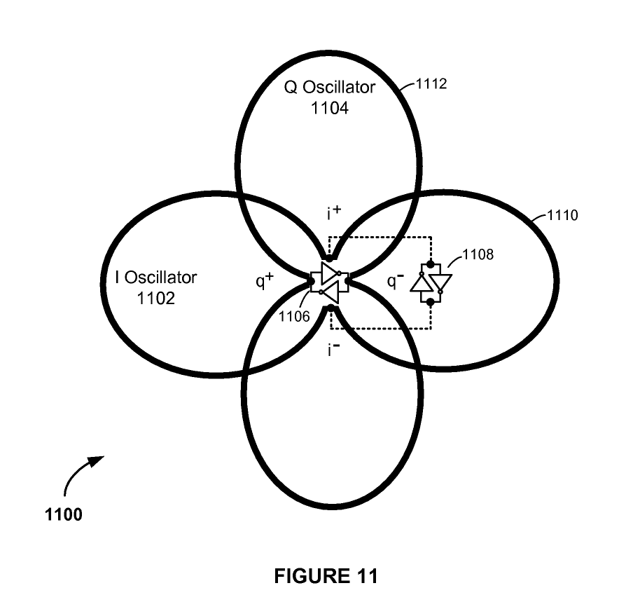

FIG. 11 is a drawing of a quadrature SWO 1100, according to another embodiment of the present invention. The quadrature SWO 1100 provides quadrature outputs, which may be advantageously used in a quadrature modulator to translate baseband signals to radio or millimeter-wave frequencies and/or to downconvert radio or millimeter-wave frequency signals to baseband, such as in a wireless communications transceiver. The quadrature SWO 1100 comprises an in-phase (I) oscillator 1102 having a first pair of cross-coupled inverters 1106 and a quadrature phase (Q) oscillator 1104 having a second pair of cross-coupled inverters 1108. The I and Q oscillators 1102 and 1104 are each constructed similar to the “figure 8” SWO 400 in FIG. 4 above, and are configured so that they are orthogonally oriented with respect to each other. Further, the I and Q oscillators 1102 and 1104 are each formed using a closed-loop microstrip transmission line or a closed-loop stripline transmission line. In one embodiment, the signal trace 1110 of the I oscillator is formed in a first horizontal plane and the signal trace 1112 of the Q oscillator is formed in a different second horizontal plane which is vertically displaced from the first horizontal plane. Although the invention is not so limited, forming the signal traces 1110 and 1112 of the I an Q oscillators 1102 and 1104 in different planes obviates the need for cross-over networks to couple the I and Q oscillators 1102 and 1104.

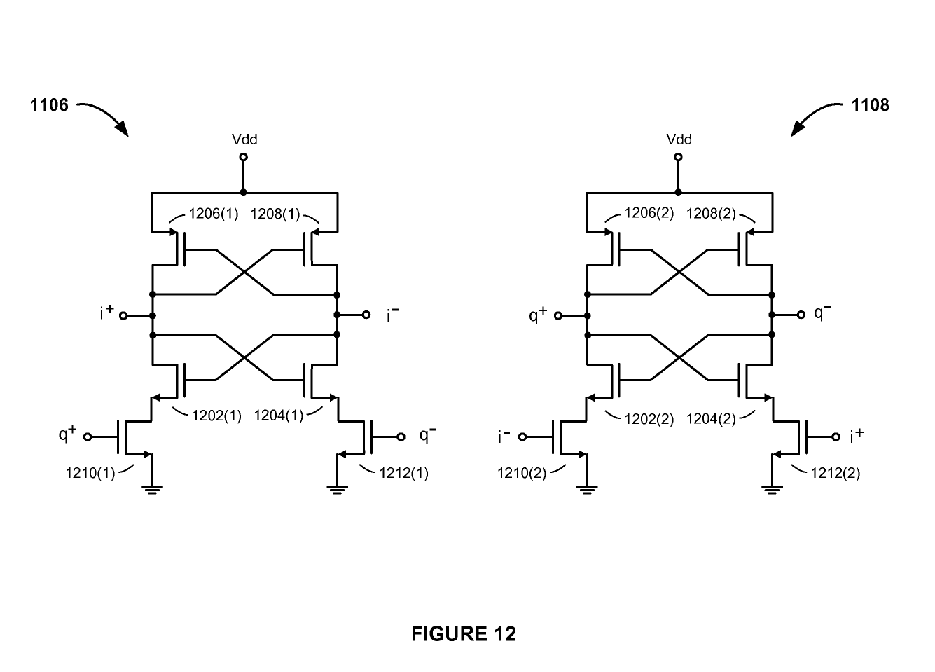

FIG. 12 illustrates how the first and second pairs of cross-coupled inverters 1106 and 1108 of the I and Q oscillators 1102 and 1104 are configured. The first pair of cross-coupled inverters 1106 is comprised of first and second cross-coupled NMOS transistors 1202(1) and 1204(1), first and second cross-coupled PMOS transistors 1206(1) and 1208(1), and first and second series enabling transistors 1210(1) and 1212(1). Similarly, the second pair of cross-coupled inverters 1108 is comprised of first and second cross-coupled NMOS transistors 1202(2) and 1204(2), first and second cross-coupled PMOS transistors 1206(2) and 1208(2), and first and second series enabling transistors 1210(2) and 1212(2). The first and second pairs of cross-coupled inverters 1106 and 1108 are coupled to each other as shown by the i⁺, i⁻, q⁺ and q⁻ labels, which correspond to the input and output nodes of the first and second pairs of cross-coupled inverters 1106 and 1108. When configured in this manner, the first and second pairs of cross-coupled inverters 1106 and 1108 perform a quadrature injection locking process that forces the I and Q oscillators 1102 and 1104 to oscillate in quadrature.

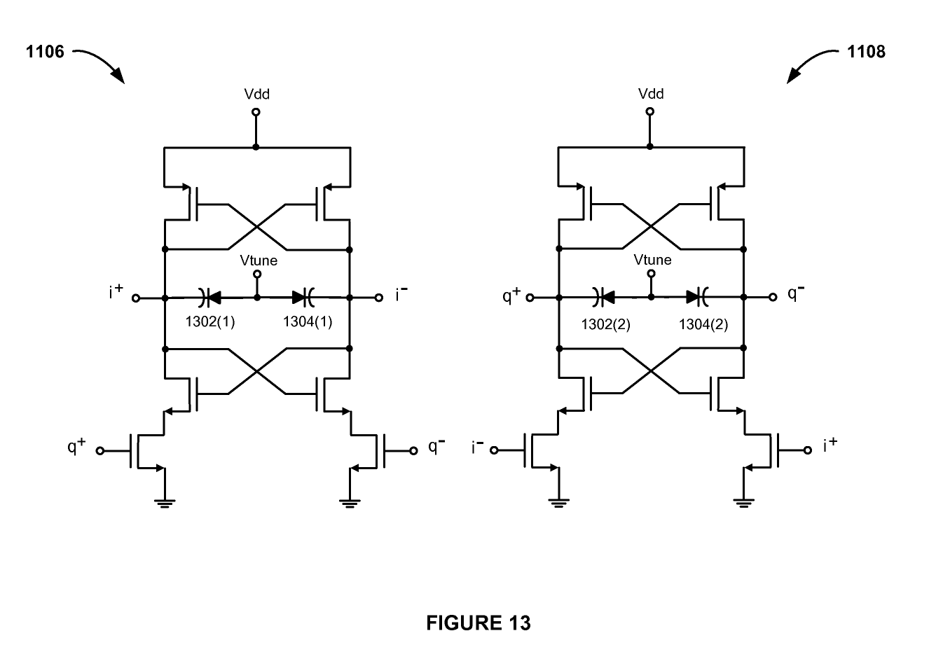

In some applications it may be necessary or desirable to tune the frequency of the quadrature SWO 1100. Some degree of tuning can be provided by use of varactors. For example, as shown in FIG. 13, first and second varactors 1302(1) and 1304(1) may be configured between the i⁺ and i⁻ nodes of the first pair of cross-coupled inverters 1106 and first and second varactors 1308(2) and 1310(2) may be between the q⁺ and q⁻ nodes of the second pair of cross-coupled inverters 1108. The capacitances of the varactors are controlled by a tuning voltage Vtune.

Although the present invention has been described with reference to specific embodiments, these embodiments are merely illustrative and not restrictive of the present invention. Further, various modifications or changes to the specifically disclosed exemplary embodiments will be suggested to persons skilled in the art and are to be included within the spirit and purview of this application and scope of the appended claims.

What is claimed is:

1. A standing wave oscillator (SWO), comprising:
a transmission line including a closed-loop single signal trace formed in a first plane and one or more ground planes formed in one or more planes parallel to but different than said first plane; and
a first pair of cross-coupled inverters having a first port coupled to a first location on the closed-loop single signal trace and a second port coupled to a second location on the closed-loop single signal trace.

2. The SWO of claim 1 wherein the closed-loop single signal trace is symmetrical about a line passing through the first and second ports of the pair of cross-coupled inverters.

3. The SWO of claim 1 wherein the closed-loop single signal trace is formed in the shape of a “figure 8.”

4. The SWO of claim 3 wherein said transmission line comprises a microstrip transmission line.

5. The SWO of claim 3 wherein said transmission line comprises a stripline transmission line.

6. A standing wave oscillator (SWO), comprising:
a first transmission line including a first closed-loop single signal trace;
a second transmission line including a second closed-loop single signal trace;
a first pair of cross-coupled inverters having a first port coupled to a first location on the first closed-loop single signal trace and a second port coupled to a second location on the first closed-loop single signal trace; and
a second pair of cross-coupled inverters electrically coupled to said first pair of cross-coupled inverters having a first port coupled to a first location on the second closed-loop single signal trace and a second port coupled to a second location on the second closed-loop single signal trace.

7. The SWO of claim 6 wherein said first and second transmission lines comprise microstrip transmission lines.

8. The SWO of claim 6 wherein said first and second transmission lines comprise stripline transmission lines.

9. The SWO of claim 6 wherein the first closed-loop single signal trace of said first transmission line is formed in the shape of a first “figure 8,” the second closed-loop single signal trace of said second transmission line is formed in the shape of a second “figure 8,” and the first and second “figure 8” shaped closed-loop single signal traces are configured so that they are orthogonally oriented to each other.

10. The SWO of claim 6 wherein the first closed-loop single signal trace of said first transmission line is formed in a first plane and the second closed-loop single signal trace of said second transmission line is formed in a second plane different than said first plane.

11. The SWO of claim 6 wherein the first and second closed-loop single signal traces and the first and second pairs of cross-coupled inverters are configured so that the SWO provides quadrature outputs.

12. The SWO of claim 6 wherein said first and second pairs of cross-coupled inverters are configured to provide an injection locking function that causes the SWO to provide quadrature outputs.

13. The SWO of claim 6 wherein said first and second pairs of cross-coupled inverters each includes frequency tuning circuitry.

14. The SWO of claim 13 wherein the frequency tuning circuitry comprises one or more varactors.

15. A method of forming a standing wave, comprising:
generating a clockwise (CW) traveling wave in a closed-loop single trace transmission line;
generating a counter-clockwise (CCW) traveling wave in said closed-loop single trace transmission line;
compensating for losses said CW and CCW traveling waves experience as they propagate along said close-loop single trace transmission line; and
combining said CW and CCW traveling waves to form a standing wave.

16. The method of claim 15 wherein compensating for losses said CW and CCW traveling waves experience as they propagate along said close-loop single trace transmission line is performed by a pair of cross-coupled inverters coupled between first and second locations along said closed-loop single trace transmission line.

17. The method of claim 15 wherein said closed-loop single trace transmission line comprises a microstrip transmission line.

18. The method of claim 15 wherein said closed-loop single trace transmission line comprises a stripline transmission line.

19. The method of claim 15 wherein said closed-loop single trace transmission line is formed in the shape of a “figure 8”.

20. A method of generating first and second standing waves that are in quadrature, comprising:
generating a first standing wave in a first closed-loop single trace transmission line;
generating a second standing wave in a second closed-loop single trace transmission line; and
forcing said first and second standing waves to be in quadrature.

21. The method of claim 20 wherein forcing said first and second standing waves to be in quadrature is performed by application of a quadrature injection locking process.

22. The method of claim 20 wherein said first and second closed-loop single trace transmission lines comprise first and second microstrip transmission lines.

23. The method of claim 20 wherein said first and second closed-loop single trace transmission lines comprise first and second stripline transmission lines.

24. The method of claim 20 wherein said first and second closed-loop single trace transmission lines are each formed in the shape of a “figure 8”.

25. The method of claim 24 wherein said first and second closed-loop single trace transmission lines are configured so that they are orthogonally oriented to each other.

26. The method of claim 20 wherein frequencies of said first and second standing waves are tunable.
